(19) United States
(12) Patent Application Publication
(10) Pub. No.: US 2026/0301796 A1
(43) Pub. Date: Oct. 1, 2026

(54) SINGLE-LINE SENSE AMPLIFIER CONTROL

(71) Applicant: Micron Technology, Inc., Boise, ID (US)

(72) Inventors: Jackson Metz, Boise, ID (US); Jiyun Li, Boise, ID (US); Shizhong Mei, Boise, ID (US); Vikrant Upadhyaya, Boise, ID (US)

(21) Appl. No.: 19/459,739

(22) Filed: Jan. 26, 2026

Related U.S. Application Data
(60) Provisional application No. 63/778,996, filed on Mar. 27, 2025.

(51) Int. Cl. G11C 11/4091

(52) U.S. Cl. CPC G11C 11/4091

(57) ABSTRACT

Devices and techniques are provided for mitigating (e.g., reducing or eliminating) timing variations of control signals (e.g., SAN signals, SAP signals) for sense amplifiers of a memory device. A single-line control signal from a control block of a memory bank of the memory device is used to drive local section drivers to generate both the SAN signal(s) and the SAP signal(s). Timing control technology and circuitry are used to control the timing among the SAN signals and the SAP signals. The timing variations among the SAN signals and the SAP signals are reduced across the sections within the memory bank, which improves the sense margin of the SAs and also improves the system performance. In addition, the current technology and methods improve area efficiency in the memory devices since less components are used to generate the SAN signals and the SAP signals.

### CROSS-REFERENCE TO RELATED APPLICATIONS

This application claims priority to U.S. Provisional Application No. 63/778,996, filed Mar. 27, 2025, which is incorporated by reference herein in its entirety.

### BACKGROUND OF THE INVENTION

### Field of the Invention

The present invention relates generally to the field of memory devices. More specifically, embodiments of the present disclosure relate to mitigating (e.g., reducing or eliminating) timing variations of control signals (e.g., SAN signals, SAP signals) in memory devices.

### Description of the Related Art

This section is intended to introduce the reader to various aspects of art that may be related to various aspects of the present invention, which are described and/or claimed below. This discussion is believed to be helpful in providing the reader with background information to facilitate a better understanding of the various aspects of the present invention. Accordingly, it should be understood that these statements are to be read in this light, and not as admissions of prior art.

Memory devices are widely used to store information related to various electronic devices such as computers, wireless communication devices, cameras, digital displays, and the like. Memory devices are frequently provided as internal memory, integrated circuits and/or external removable devices in computers or other electronic devices. There are many different types of memory, including volatile and non-volatile memory. Volatile memory, including random access memory (RAM), static random access memory (SRAM), dynamic random access memory (DRAM), and synchronous dynamic random access memory (SDRAM), among others, may require a source of applied power to maintain its data. Non-volatile memory, by contrast, may retain its stored data even when not externally powered. Non-volatile memory is available in a wide variety of technologies, including flash memory (e.g., NAND and NOR) phase change memory (PCM), ferroelectric random access memory (FeRAM), resistive random access memory (RRAM), and magnetic random access memory (MRAM), among others.

A memory device may include a number of storage elements, such as memory cells. The memory device may include a number of memory banks each including a number of rows and/or columns of memory cells. Memory cells of a binary memory device may, for example, include a charged or discharged capacitor. A charged capacitor of a memory cell may, however, become discharged over time through leakage currents, resulting in the loss of the stored information. Certain features of volatile memory may offer performance advantages, such as faster read or write speeds, while features of non-volatile memory, such as the ability to store data without periodic refreshing, may be advantageous in other applications. Some of the memory devices include memory cells that may be accessed by turning on a transistor that couples the memory cell (e.g., the capacitor) with a wordline or a bitline/digit line. Different memory devices may use different architectures for arranging the memory cells. For example, different memory devices may arrange the memory cells in 2-dimensional or 3-dimensional rows and columns. A memory cell may be accessed based on activating a row and a column of the memory device corresponding to the memory cell.

Sense amplifiers (SAs) may be used by a memory device during read/write operations. For example, the read circuitry of the memory device utilizes the sense amplifiers to receive low voltage (e.g., low differential) signals and amplify the small voltage differences to enable the memory device to interpret the data properly. A sense amplifier (SA) may include multiple devices (e.g., an isolation gate, a PMOS sense amplifier (PSA), an NMOS sense amplifier (NSA)). A SAN signal may be used to control a RNL (row Nsense latch) signal of the SA to enable or disable the activation of the NSAs in the SA. A SAP signal may be used to control an ACT (activate) signal of the SA to enable or disable the activation of the PSAs in the SA. Each memory bank of the memory device may include one or more sense amplifiers, and the SAN signal and the SAP signal are generated by local section drivers using corresponding control signals (e.g., a RSAN signal for the SAN signal, a RSAP signal for the SAP signal) driven from a bank logic circuit (e.g., a control block) of the memory bank to local section drivers. To obtain improved sense margin, it is desired to keep the timing among the SAN signals and the SAP signals consistent across sections within a memory bank. However, routing, coupling, and loading differences among the control signals for the SAN signals and the SAP signals may cause timing variations (e.g., timing skew) among the SAN signals and the SAP signals as the control signals propagate from sections near the bank logic circuit to sections far from the bank logic circuit.

### BRIEF DESCRIPTION OF THE DRAWINGS

Various aspects of this disclosure may better be understood upon reading the following detailed description and upon reference to the drawings in which:

FIG. 1 is a block diagram illustrating certain features of a memory device, according to an embodiment of the present disclosure;

FIG. 2 illustrates a memory bank of the memory device of FIG. 1, according to an embodiment of the present disclosure;

FIG. 3 is a circuit diagram illustrating a sense amplifier of the memory device of FIG. 1, according to an embodiment of the present disclosure;

FIGS. 4A and 4B illustrate an embodiment of control circuitry using a single-line control signal to generate a SAN signal and a SAP signal, according to an embodiment of the present disclosure;

FIG. 5 is a timing diagram illustrating a relationship of the maximum magnitude of the voltage difference between the gate and the source of a switch device and the turn on time of the switch device, according to an embodiment of the present disclosure;

FIGS. 6A and 6B illustrate a second embodiment of control circuitry using a single-line control signal to generate more than one SAN signal and a single-line control signal to generate more than one SAP signal, according to an embodiment of the present disclosure;

FIG. 7 is a timing diagram illustrating relationships of signals SAN_ON, SAP_ON, RSANs, RSAPs, SANs, and SAPs, according to an embodiment of the present disclosure;

FIG. 8 illustrates another embodiment of control circuitry using a single-line control signal to generate more than one SAN signal and more than one SAP signal, according to an embodiment of the present disclosure;

FIG. 9 is a timing diagram illustrating relationships of signals SAN_ON, SAP_OFF, RSANs, RSAPs, SANs, and SAPs, according to an embodiment of the present disclosure; and

FIG. 10 is a flow diagram of a method for implementing a single-line control signal to generate both the SAN signal and the SAP signal, according to an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

A memory device may perform memory operations such as storing data (e.g., write operations) and retrieving stored data (e.g., read operations). For example, a computing system may include various system components including one or multiple memory devices. The system components may communicate data (e.g., data bits) to perform system operations. For example, the system may include one or more processing components, and one or more memory devices, among other system components. In different embodiments, the computing system may be disposed on a single electronic chip or multiple electronic chips. Moreover, the computing system may be disposed on a single electronic device or multiple electronic devices positioned in proximity of or remote from each other.

The memory device may include a number of memory banks, controller circuitry, command decoder circuitry, and a clock circuit to provide the clock signal, among other memory components. In some cases, the controller circuitry (hereinafter, controller) may include the command decoder circuitry (hereinafter, command decoder). In alternative or additional cases, the command decoder may include separate circuitry disposed between the controller and the memory banks or any other viable location. The memory device may include control circuitry (e.g., control blocks) associated with the memory banks. In some cases, the command decoder may provide the access instructions to the control blocks of the memory banks. The memory banks and/or the control blocks of the memory banks may include sense amplifiers (SAs) used for read operations of the memory device. A sense amplifier (SA) may include multiple devices (e.g., an isolation gate, a PMOS sense amplifier (PSA), an NMOS sense amplifier (NSA)). A SAN signal may be used to control a RNL (row Nsense latch) signal of the SA to enable or disable the activation of the NSAs in the SA. A SAP signal may be used to control an ACT (activate) signal of the SA to enable or disable the activation of the PSAs in the SA. Each memory bank of the memory device may include one or more sense amplifiers, and the SAN signal and the SAP signal are generated by local section drivers using corresponding control signals (e.g., a RSAN signal for the SAN signal, a RSAP signal for the SAP signal) driven from a bank logic circuit (e.g., a control block) of the memory bank to local section drivers.

To obtain improved sense margin, it is desired to keep the timing among the SAN signals and the SAP signals consistent across sections within a memory bank. However, routing, coupling, and loading differences among the control signals for the SAN signals and the SAP signals may cause timing variations as the control signals propagate from sections near the bank logic circuit to sections far from the bank logic. Timing variations among the SAN signals and the SAP signals may reduce overall sense margin, which may affect the system performance. Accordingly, it is desirable to control the timing between the SAN signals and the SAP signals to reduce or eliminate the timing variations.

The current disclosure is related to mitigating (e.g., reducing or eliminating) timing variations of control signals (e.g., SAN signals, SAP signals) for the sense amplifier of a memory device. A single-line control signal from a control block of a memory bank of the memory device may be used to drive local section drivers to generate both the SAN signal(s) and the SAP signal(s) for the sense amplifier. In some embodiments, a single-line control signal from the control block of the memory bank may be used to generate a SAN signal and a SAP signal. In some embodiments, a single-line control signal from the control block of the memory bank may be used to generate more than one SAN signal, and another single-line control signal from the control block of the memory bank may be used to generate more than one SAP signal. In some embodiments, a single-line control signal from the control block of the memory bank may be used to generate more than one SAN signal and more than one SAP signal. The single-line control signal may propagate to the local section drivers for the SAN signal and the SAP signal through sections near the control block to sections far from the control block within the memory bank. Accordingly, the timing variations among the SAN signals and the SAP signals may be reduced across the sections within the memory bank, which improves the sense margin and also improves the system performance. Timing control technology and circuitry may be used to control the timing among the SAN signals and the SAP signals. In addition, the current technology and methods improve area efficiency in the memory device since less components may be used to generate the SAN signals and the SAP signals.

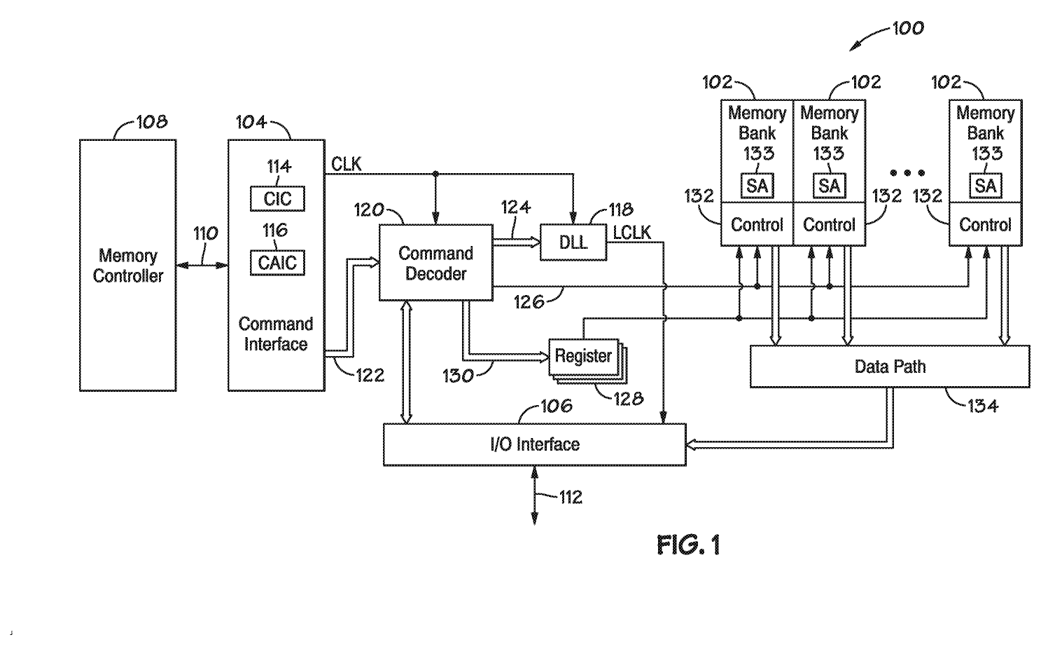

Turning now to the figures, FIG. 1 depicts a simplified block diagram illustrating certain features of a memory device 100 (e.g., a memory subsystem of an apparatus). Specifically, the block diagram of FIG. 1 depicts a functional block diagram illustrating certain functionality of the memory device 100. In accordance with one embodiment, the memory device 100 may include a random access memory (RAM) device, a ferroelectric RAM (FeRAM) device, a dynamic RAM (DRAM) device, a static RAM (SRAM) device (including a double data rate SRAM device), flash memory, and/or a 3D memory array including phase change (PC) memory and/or other chalcogenide-based memory, such as self-selecting memories (SSM). Moreover, each memory cell of such 3D memory array may include a corresponding logic storing device (e.g., a capacitor, a resistor, or the resistance of the chalcogenide material(s)).

The memory device 100 may include a number of memory banks 102 each including one or more memory arrays. Various configurations, organizations, and sizes of the memory banks 102 on the memory device 100 may be used based on an application and/or design of the memory device 100 within an electrical system. For example, in different embodiments, the memory banks 102 may include a different number of rows and/or columns of memory cells. Moreover, the memory banks 102 may each include a number of pins for communicating with other blocks of the memory device 100. For example, each memory bank 102 may receive one data bit per pin at each clock cycle. Furthermore, the memory banks 102 may be grouped into multiple memory groups (e.g., two memory groups, three memory groups).

The memory device 100 may also include a command interface 104 and an input/output (I/O) interface 106. The command interface 104 is configured to provide a number of signals received from a processor (e.g., a processor subsystem of an apparatus) or a controller, such as a memory controller 108. In different embodiments, the memory controller 108, hereinafter controller 108, may include one or more processors (e.g., memory processors), one or more programmable logic fabrics, or any other suitable processing components.

In some embodiments, a bus 110 may provide a signal path or a group of signal paths to allow bidirectional communication between the controller 108, the command interface 104 and the I/O interface 106. For example, the controller 108 may receive memory access requests from the I/O interface via the command interface 104 and the bus 110. Moreover, the controller 108 may provide the access commands and/or access instructions for performing memory operations to the command interface 104 via the bus 110.

Similarly, an external bus 112 may provide another signal path or group of signal paths to allow for bidirectional transmission of signals, such as data signals and access commands (e.g., read/write requests), between the I/O interface 106, the controller 108, a command decoder 120, and/or other components. Thus, the controller 108 may provide various signals (e.g., the access commands, the access instructions, or other signals) to different components of the memory device 100 to facilitate the transmission and receipt of data to be written to or read from the memory banks 102.

That said, the command interface 104 may receive different signals from the controller 108. For example, a reset command may be used to reset the command interface 104, status registers, state machines and the like, during power-up. Various testing signals may also be provided to the memory device 100. For example, the controller 108 may use such testing signals to test connectivity of different components of the memory device 100. In some embodiments, the command interface 104 may also provide an alert signal to the controller 108 upon detection of an error in the memory device 100. Moreover, the I/O interface 106 may additionally or alternatively be used for providing such alert signals, for example, to other system components electrically connected to the memory device 100.

The command interface 104 may also receive one or more clock signals from an external device (e.g., an external clock signal). Moreover, the command interface 104 may include a clock input circuit 114 (CIC) and a command address input circuit 116 (CAIC). The command interface 104 may use the clock input circuit 114 and the command address input circuit 116 to receive the input signals, including the access commands, to facilitate communication with the memory banks 102 and other components of the memory device 100.

Moreover, the clock input circuit 114 may receive the one or more clock signals (e.g., the external clock signal) and may generate an internal clock signal (CLK) therefrom. In some embodiments, the command interface 104 may provide the CLK to the command decoder 120 and an internal clock generator, such as a delay locked loop (DLL) 118 circuit. The DLL 118 may generate a phase controlled internal clock signal (LCLK) based on the received CLK. For example, the DLL 118 may provide the LCLK to the I/O interface 106. Subsequently, the I/O interface 106 may use the received LCLK as a clock signal for transmitting the read data using the external bus 112.

The command interface 104 may also provide the internal clock signal CLK to various other memory components. As mentioned above, the command decoder 120 may receive the internal clock signal CLK. In some cases, the command decoder 120 may also receive the access commands via a bus 122 and/or through the I/O interface 106 received via the external bus 112. For example, the command decoder 120 may receive the access commands through the I/O interface 106 transmitted by one or more external devices. In some cases, a processor may transmit the access commands.

The command decoder 120 may decode the access commands and/or the memory access requests to provide corresponding access instructions for accessing target memory cells. For instance, the command decoder 120 may provide the access instructions to one or more control blocks 132 associated with the memory banks 102 via a bus path 126. In some cases, the command decoder 120 may provide the access instructions to the control blocks 132 in coordination with the DLL 118 over a bus 124. For example, the command decoder 120 may coordinate generation of the access instructions in-line (e.g., synchronized) with the CLK and/or LCLK. In some cases, the command decoder 120 may receive the access commands using a rising edge and/or a falling edge of the external clock signal. For example, a processor may transmit the access commands using a memory command protocol, such as a single clock cycle memory command protocol, or a multi-clock cycle memory command protocol. The processor may use a specific memory command protocol based at least in part on the number of pins of the memory device 100 or the I/O interface 106, the number of rows and/or columns of the memory banks 102, and the number of memory banks 102. Subsequently, the command decoder 120 may provide the access instructions to the memory banks 102 based on receiving and decoding the access commands.

Accordingly, the command decoder 120 may provide the access instructions to the memory banks 102 using one or multiple clock cycles of the CLK via the bus path 126. The command decoder 120 may also transmit various signals to one or more registers 128 via, for example, one or more global wiring lines 130. Moreover, the memory device 100 may include other decoders, such as row decoders and column decoders, to facilitate access to the memory banks 102, as discussed below.

In some embodiments, each memory bank 102 may include a respective control block 132. In some cases, each of the control blocks 132 may also provide row decoding and column decoding capability based on receiving the access instructions. Accordingly, the control block 132 may facilitate accessing the memory cells of the respective memory banks 102. For example, the control blocks 132 may include circuitry (e.g., logic circuitry) to facilitate accessing the memory cells of the respective memory banks 102 based on receiving the access instructions. For example, each memory bank 102 and/or corresponding control block 132 may include sense amplifiers (SAs) 133 for read operations of the memory cells of respective memory bank 102.

In some cases, the control blocks 132 may receive the access instructions and determine target memory banks 102 associated with the target memory cells. In specific cases, the command decoder 120 may include the control blocks 132. Moreover, the control blocks 132 may also provide timing control (e.g., for SAN signals and SAP signals) and data control functions to facilitate execution of different commands with respect to the respective memory banks 102.

Furthermore, the command decoder 120 may provide register commands to the one or more registers 128 to facilitate operations of one or more of the memory banks 102, the control blocks 132, and the like. For example, one of the one or more registers 128 may provide instructions to configure various modes of programmable operations and/or configurations of the memory device 100. The one or more registers 128 may be included in various memory devices to provide and/or define operations of various components of the memory device 100.

In some embodiments, the one or more registers 128 may provide configuration information to define operations of the memory device 100. For example, the one or more registers 128 may include operation instructions for DRAMs, synchronous DRAMs, FeRAMs, chalcogenide memories (e.g., SSM memory, PC memory), or other types of memories. As discussed above, the one or more registers 128 may receive various signals from the command decoder 120, or other components, via the one or more global wiring lines 130.

In some embodiments, the one or more global wiring lines 130 may include a common data path, a common address path, a common write command path, and a common read command path. The one or more global wiring lines 130 may traverse across the memory device 100, such that each of the one or more registers 128 may couple to the global wiring lines 130. The additional registers may involve additional wiring across the memory device (e.g., die), such that the registers are communicatively coupled to the corresponding memory components.

The I/O interface 106 may include a number of pins (e.g., 7 pins) to facilitate data communication with external components (e.g., the processing component, such as a processor). Particularly, the I/O interface 106 may receive the access commands via the pins. Moreover, data stored on the memory cells of the memory banks 102 may be transmitted to and/or retrieved from the memory banks 102 over a data path 134. The data path 134 may include a plurality of bi-directional data buses to one or more external devices via the I/O interface 106. For certain memory devices, such as a DDR5 SDRAM memory device, the I/O signals may be divided into upper and lower bytes; however, such segmentation is not utilized in conjunction with other memory device types.

That said, in different embodiments, the memory device 100 may include additional or alternative components. That is, the memory device 100 may include additional or alternative components such as power supply circuits (for receiving external VDD and VSS signals), read/write amplifiers (to amplify signals during read/write operations), temperature sensors (for sensing temperatures of the memory device 100), etc. Accordingly, it should be understood that the block diagram of FIG. 1 is only provided to highlight certain functional features of the memory device 100 to aid in the subsequent detailed description.

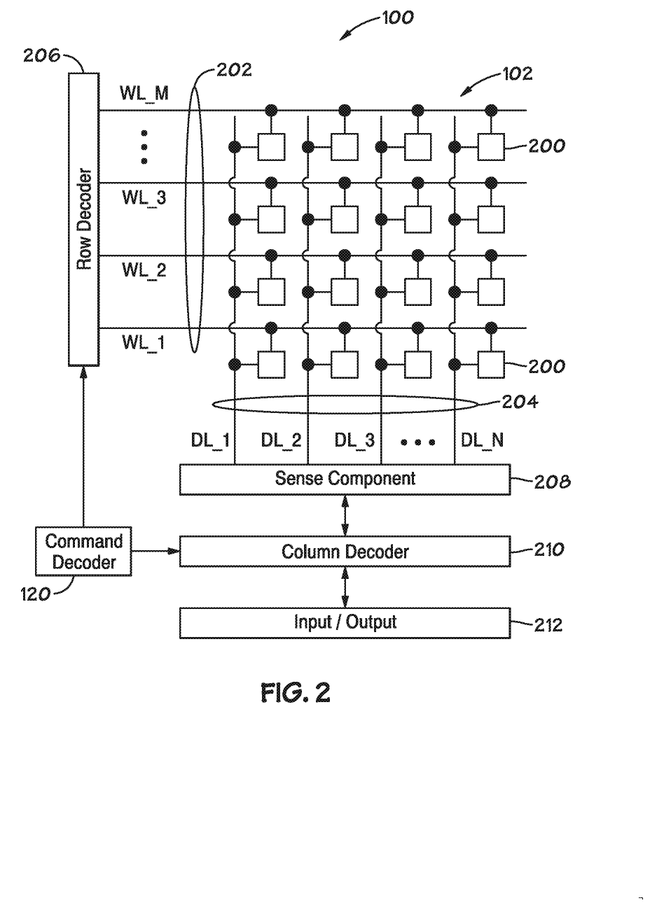

Referring now to FIG. 2, a memory bank 102 of the memory device 100 is illustrated in accordance with various examples of the present disclosure. The memory bank 102 may include a number of memory cells 200 that are programmable to store different memory states. In the depicted embodiment, the memory cells 200 may be arranged in multiple rows (e.g., 22 rows, 19 rows, etc.) and multiple columns.

Memory operations, such as reading and writing memory states, may be performed on the memory cells 200 by activating or selecting the appropriate word lines 202 and digit lines 204. Activating or selecting a word line 202 or a digit line 204 may include applying a voltage to the respective lines. The word lines 202 and the digit lines 204 may include conductive materials.

For example, word lines 202 and digit lines 204 may be made of metals (such as copper, aluminum, gold, tungsten, etc.), metal alloys, other conductive materials, or the like. In the depicted embodiment, each row of the memory cells 200 is connected to a single word line 202, and each column of the memory cells 200 is connected to a single digit line 204. Moreover, each of the memory cells 200 may be associated with a row and a column of the memory bank 102. Accordingly, each of the memory cells 200 is connected to a respective word line 202 and a respective digit line 204.

By applying a voltage to a single word line 202 and a single digit line 204, a single memory cell 200 may be activated (or accessed) at their intersection. Accessing the memory cell 200 may include performing reading or writing operation on the memory cell 200. For example, a read operation may include sensing a charge level from the memory cell 200. The intersection of a word line 202 and digit line 204 may be referred to as an address of a respective memory cell 200. Accordingly, the command decoder 120 may provide the access instructions, including the address bits, to indicate the word lines 202 and digit lines 204 corresponding to the target memory cells 200.

In some architectures, the memory state storage of the memory cell 200 (e.g., a capacitor) may be electrically isolated from the digit line by a selection component. The word line 202 may be connected to and may control the selection component. For example, the selection component may be a transistor and the word line 202 may be connected to the gate of the transistor. Activating the word line 202 may result in an electrical connection or closed circuit between the capacitor of the memory cell 200 and its corresponding digit line 204. The digit line 204 may then be activated to either read or write the memory cell 200.

Accordingly, accessing the memory cell 200 may be controlled through a respective row decoder 206 and a respective column decoder 210. As mentioned above, in different embodiments, the controller 108, the command decoder 120, and/or the control blocks 132 may include the row decoder 206 and/or the column decoder 210. In some examples, the row decoder 206 may receive a row address from the command decoder 120 and may activate the appropriate word line 202 based on the received row address.

Similarly, a column decoder 210 may receive a column address from the command decoder 120 and may activate the appropriate digit line 204. The command decoder 120 may provide the row address and the column address based on receiving and decoding the access commands and providing the access instructions. For example, the memory bank 102 may include multiple word lines 202, labeled WL_1 through WL_M, and multiple digit lines 204, labeled DL_1 through DL_N, where M and N depend on the array size. Thus, by activating a word line 202 and a digit line 204, e.g., WL_2 and DL_3, the memory cell 200 at their intersection may be accessed.

In any case, upon accessing, the memory cell 200 may be read, or sensed, by a sense component 208 (e.g., includes one or more sense amplifiers (SAs) 133) to determine the stored state of the memory cell 200. For example, after accessing the memory cell 200, a ferroelectric capacitor of the memory cell 200 may discharge a first charge (e.g., a dielectric charge) onto its corresponding digit line 204. In other examples, after accessing the memory cell 200, the ferroelectric capacitor of the memory cell 200 may discharge a second or third charge (e.g., a polarization charge) onto its corresponding digit line 204. Discharging the ferroelectric capacitor may be based on biasing, or applying a voltage, to the ferroelectric capacitor.

The discharging may induce a change in the voltage of the digit line 204, which sense component 208 may compare to a reference voltage (not shown) in order to determine the stored state of the memory cell 200. For example, if the digit line 204 has a higher voltage than the reference voltage, then sense component 208 may determine that the stored state in the memory cell 200 is related to a first predefined memory state. In some cases, the first memory state may include a state 1, or may be another value—including other logic values associated with multi-level sensing that enables storing more than two values (e.g., 3 states per cell or 1.5 bits per cell). The sense component 208 may include various transistors or amplifiers in order to detect and amplify a difference in the signals, which may be referred to as latching. The detected logic state of the memory cell 200 may then be output through column decoder 210 as output 212.

In some examples, detecting and amplifying a difference in the signals may include latching a charge that is sensed in sense component 208. One example of this charge may include latching a dielectric charge associated with the memory cell 200. As an example, the sense component 208 may sense a dielectric charge associated with the memory cell 200. The sensed dielectric charge may be latched in a latch within the sense component 208 or a separate latch that is in electronic communication with the sense component 208.

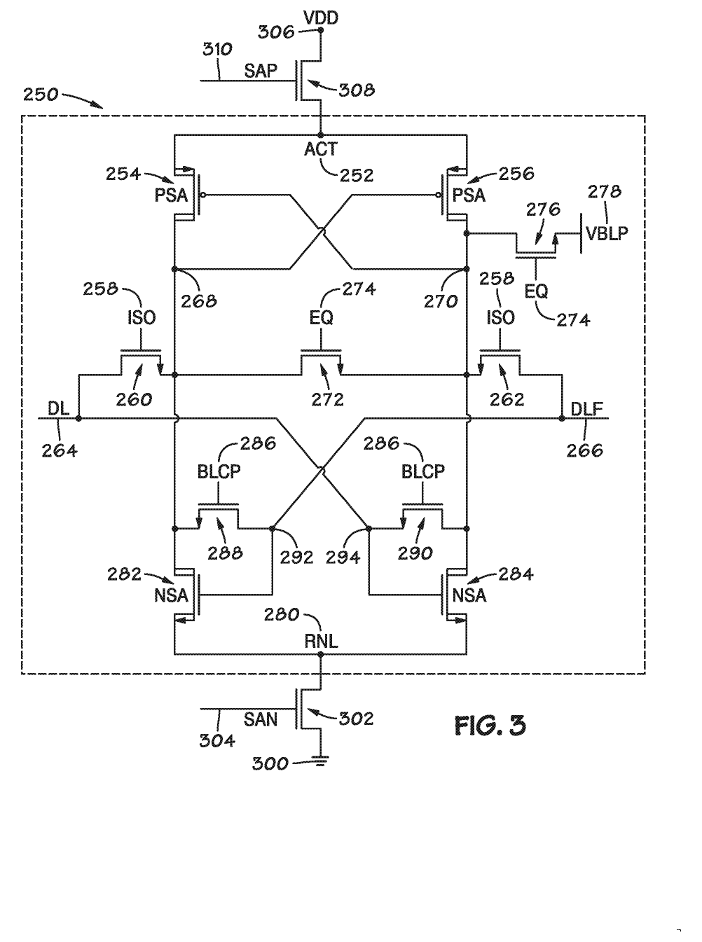

FIG. 3 is a circuit diagram of a sense amplifier 250 that may be implemented as an embodiment of the sense amplifiers 133 of FIG. 1. Although only a single sense amplifier 250 is shown in FIG. 3, multiple sense amplifiers 133 may be included in the memory device 100 and may share at least some control signals and/or supply voltages.

As illustrated, the sense amplifier 250 receives an activate signal (ACT) 252 as a local voltage. The ACT 252 activates the sense amplifier 250 by providing an operating voltage to the sense amplifier 250. In particular, the ACT 252 is coupled to respective PMOS (p-channel metal-oxide semiconductor) transistors in a PMOS sense amplifier (PSA) 254 and a PMOS sense amplifier (PSA) 256 of the sense amplifier 250, respectively. In the current disclosure, terms PSA 254 and PSA 256 are referred to herein as the respective PMOS transistor in the corresponding PSA. The sense amplifier 250 also receives an isolation signal (ISO) 258, which is used by transistors 260 and 262 to couple and decouple internal circuitry of the sense amplifier 250 from respective digit lines (DL) 264 and DLF (DL flipped)) 266. The digit line (DL) 264 may be indicative of the data in the memory cell as a “bit line true” signal (BLT) while the digit line (DLF) 266 may be opposite as a complementary “bit line bar/false” signal (BLB). The transistors 260 and 262 are coupled to the PSAs 254 and 256 at gut nodes 268 and 270, respectively. Thus, the ISO 258 controls coupling of the gut node 268 to and decoupling of the gut node 268 from the digit line (DL) 264 via the transistor 260. Similarly, the ISO 258 controls coupling of the gut node 270 to and decoupling of the gut node 270 from the digit line (DLF) 266 via the transistor 262. Gut nodes 268 and 270 are each coupled to a respective first terminal (e.g., gate) of one of the PSAs 254 and 256 and a respective second terminal (e.g., drain) of the other of the PSAs 254 and 256.

Accordingly, when a voltage difference between the DL 264 and DLF 266 is greater than a threshold voltage Vth-1 of the transistors in the PSA 254 and PSA 256, one of the PSA 254 and the PSA 256 may be turned on and the other one may be turned off. For example, when the SA 250 is activated by the ACT 252 and the transistors 260 and 262 are turned on by the ISO 258, if the voltage on the DL 264 is higher than the voltage on the DLF 266 by at least the threshold voltage Vth-1, then the voltage at the gut node 268 is higher than the voltage at the gut node 270 by at least the threshold voltage Vth-1, and the PSA 254 is turned on due to the voltage at the gut node 270, which is connected to the gate of the PSA 254, is lower than the voltage at the gut node 268, which is connected to the drain of the PSA 254, by at least the threshold voltage Vth-1. In the example above, the PSA 256 is turned off due to the voltage at the gut node 268, which is connected to the gate of the PSA 256, is higher than the voltage at the gut node 270, which is connected to the drain of the PSA 256. Similarly, when the voltage on the DLF 266 is higher than the voltage on the DL 264 by at least the threshold voltage Vth-1, the PSA 256 is turned on and the PSA 254 is turned off. When either the PSA 254 or the PSA 256 is turned on, the voltage difference between the DL 264 and DLF 266 may be amplified.

The sense amplifier 250 further includes a transistor 272, which is used to equalize the voltages of the gut nodes 268 and 270 based on an equalization signal (EQ) 274. In addition, the sense amplifier 250 includes a transistor 276 coupled to the gut node 270 so that the gut node 270 may be discharged/charged to a bit line precharge voltage (VBLP) 278 via the transistor 276 when the EQ 274 is asserted.

The sense amplifier 250 further receives an RNL (row Nsense latch) signal 280. The RNL signal 280 is coupled to respective NMOS (n-channel metal-oxide semiconductor) transistors in an NMOS sense amplifier (NSA) 282 and an NMOS sense amplifier (NSA) 284 of the SA 250, respectively. The RNL signal 280 may be a voltage signal that provides an activation voltage to activate the NSA 282 and the NSA 284 (e.g., enabled via control signals in a read/write gap for the sense amplifier 250), as described in detail below. In the current disclosure, terms NSA 282 and NSA 284 are referred to herein as the respective NMOS transistors in the corresponding NSA. The SA 250 further receives a bit line compensation enable signal (BLCP) 286, which is coupled to respective gates of a transistor 288 and a transistor 290, respectively. The transistor 288 is coupled to the DLF 266 via a sense node 292, and the transistor 290 is coupled to the DL 264 via a sense node 294. Sense nodes 292 and 294 are each coupled to a respective first terminal (e.g., gate) of one of the NSAs 282 and 284 and a respective second terminal (e.g., drain) of one of the transistors 288 and 290. A respective second terminal (e.g., drain) of the NSA 282 is coupled to the gut node 268, and a respective second terminal (e.g. drain) of the NSA 284 is coupled to the gut node 270. Thus, the BLCP 286 controls coupling of the NSA 282 to and decoupling of the NSA 282 from the DLF 266 via the transistor 288. Similarly, the BLCP 286 controls coupling of the NSA 284 to and decoupling of the NSA 284 from the DL 264 via the transistor 290.

Accordingly, when a voltage difference between the DL 264 and DLF 266 is greater than a threshold voltage Vth-2 of the transistors in the NSA 282 and NSA 284, one of the NSA 282 and the NSA 284 may be turned on and the other one may be turned off. For example, when the NSA 282 and the NSA 284 are activated by the RNL signal and the transistors 288 and 290 are turned off by the BLCP 286, if the voltage on the DL 264 is higher than the voltage on the DLF 266 by at least the threshold voltage Vth-2, then the voltage at the sense node 294 is higher than the voltage at the gut node 270 by at least the threshold voltage Vth-2, and the NSA 284 is turned on due to the voltage at the sense node 294, which is connected to the gate of the NSA 284, is higher than the voltage at the gut node 270, which is connected to the drain of the NSA 284, by at least the threshold voltage Vth-2. In the example above, the NSA 282 is turned off due to the voltage at the sense node 292, which is connected to the gate of the NSA 282, is lower than the voltage at the gut node 268, which is connected to the drain of the NSA 282. Similarly, when the voltage on the DLF 266 is higher than the voltage on the DL 264 by at least the threshold voltage Vth-2, the NSA 282 is turned on and the NSA 284 is turned off. When either the NSA 282 or the NSA 284 is turned on, the voltage difference between the DL 264 and DLF 266 may be amplified.

As illustrated in FIG. 3, the RNL signal 280 may be coupled to a voltage source (e.g., ground) 300 via a switch device, such as a transistor 302 (e.g., an NMOS transistor) , and when the transistor 302 is turned on, the RNL signal 280 is connected to the voltage source 300, thereby activating the NSA 282 and the NSA 284. A SAN signal 304 may be coupled to the gate of the transistor 302 to turn on or turn off the transistor 302 to enable or disable the activation of the NSA 282 and the NSA 284. For example, when a difference between the voltage of the SAN signal 304 and the voltage source 300 coupled to the transistor 302 is greater than a threshold voltage Vth (e.g., 0.7V) of the transistor 302, the transistor 302 is turned on and the signal RNL signal 280 is connected to the voltage source 300 thereby activates the NSA 282 and the NSA 284.

As illustrated in FIG. 3, the ACT signal 252 may be coupled to a voltage source (e.g., VDD) 306 via a switch device, such as a transistor 308 (e.g., an NMOS transistor), and when the transistor 308 is turned on, the ACT signal 252 is connected to the voltage source 306, thereby activating the PSA 254 and the PSA 256. A SAP signal 310 may be coupled to the gate of the transistor 308 to turn on or turn off the transistor 308 to enable or disable the activation of the PSA 254 and the PSA 256. For example, when the voltage of the SAP signal 310 is higher than the threshold to turn on the transistor 308, the signal ACT signal 252 is connected to the voltage source 306 thereby activates the PSA 254 and the PSA 256.

In some embodiments, multiple sense amplifiers 133 may be included in different sections at different locations of a memory bank 102, and the SAN signal (e.g., the SAN signal 304) and the SAP signal (e.g., the SAP signal 310) may be generated by local section drivers using corresponding control signals driven from the control block 132 to the sense amplifiers 133 located in different sections of the memory bank 102. For example, the SAN signal 304 may be generated by the local section drivers using the control signal RSAN from the control block 132, while the SAP signal 310 may be generated by the local section drivers using the control signal RSAP from the control block 132. When the control signals (e.g., the RSAN signal, the RSAP signal) propagate from sections near the control block 132 to sections far from the control block 132, differences in routing, coupling, and loading may cause timing variations between the control signals, which may cause timing variations between the SAN signal and the SAP signal. The timing variation between the SAN signal and the SAP signal may affect the sense margin of the sense amplifiers 133.

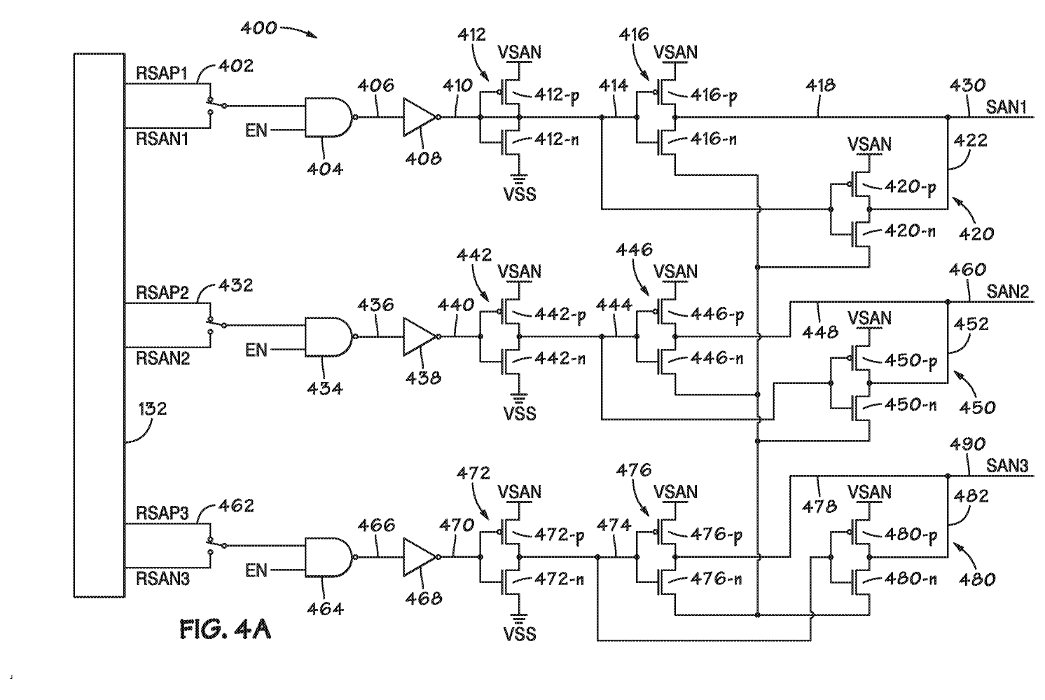

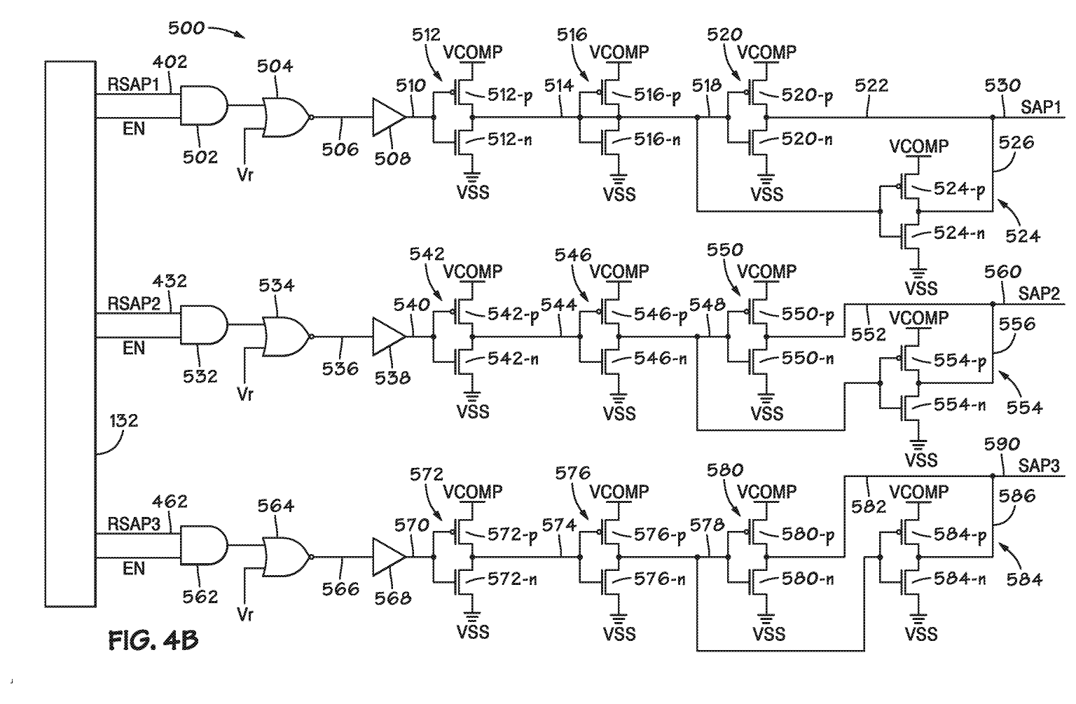

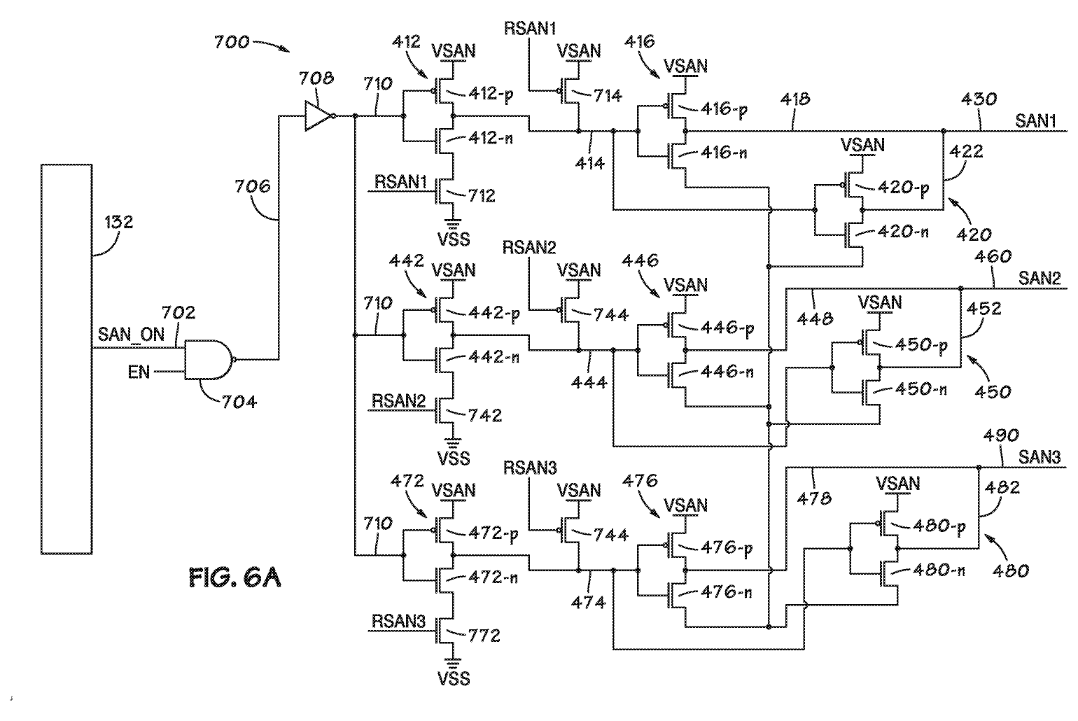

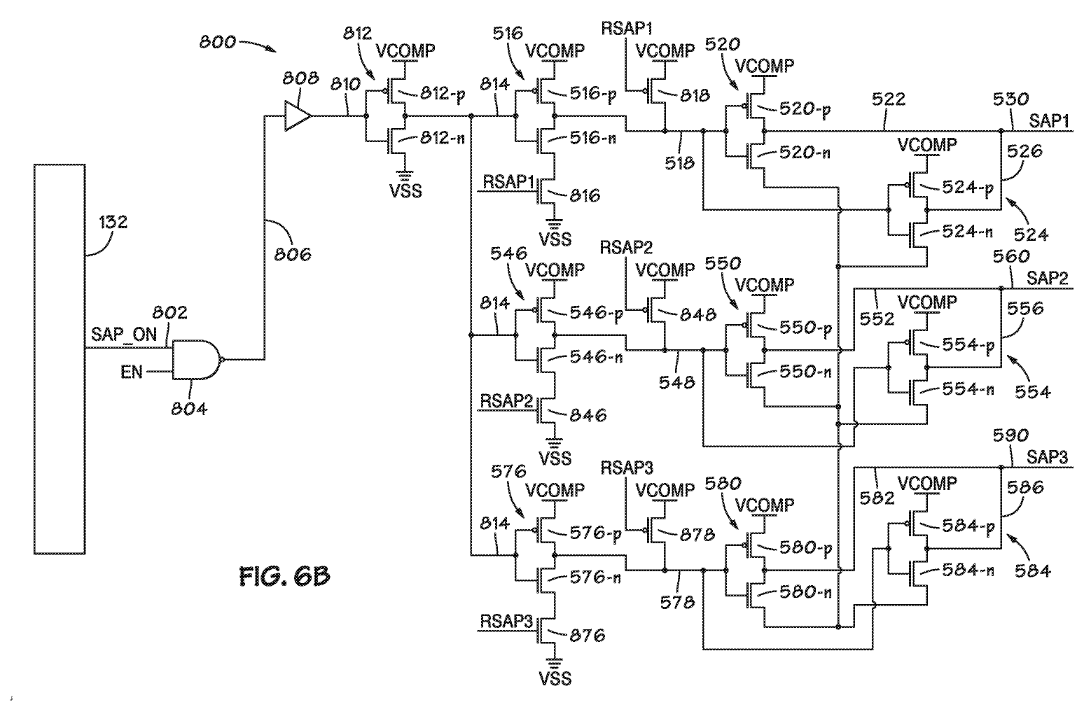

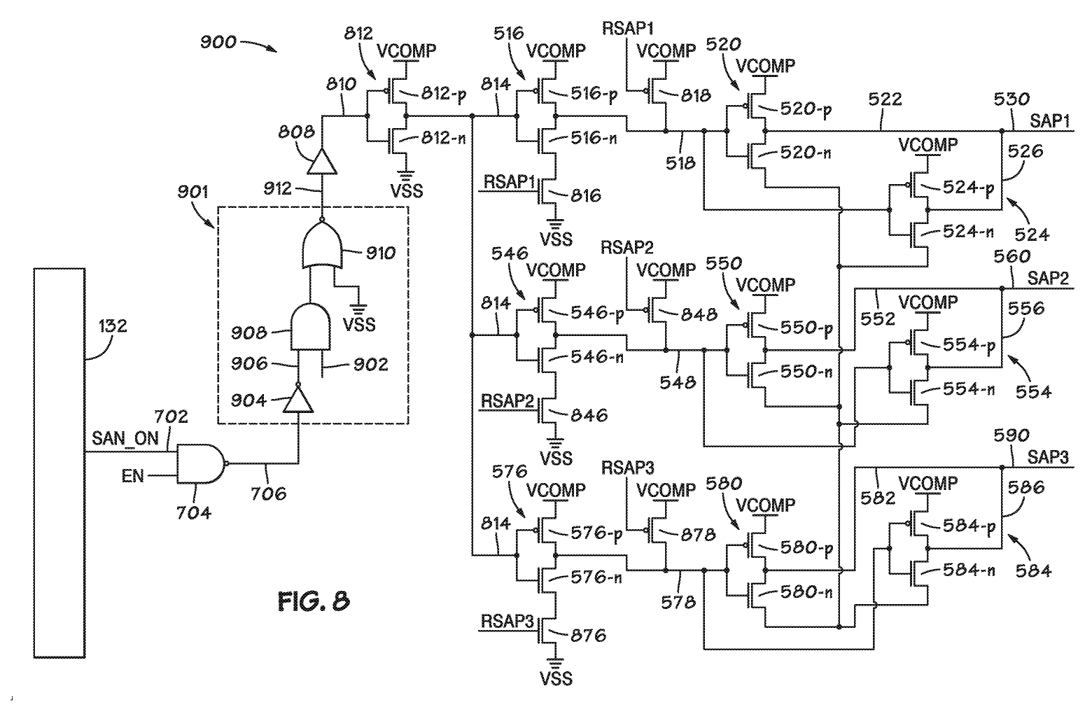

To improve the sense margin and improve the system performance of the memory device 100, it is desired to keep a consistent timing among the SAN signal and the SAP signal across sections within a memory bank 102. In some embodiments, rather than routing the RSAN signal and the RSAP signal separately from the control block 132, a single-line control signal may be used to drive local section drivers to generate both the SAN signal and the SAP signal, as illustrated in FIGS. 4A, 4B and 8. In some embodiments, a single-line control signal may be used to drive local section drivers to generate more than one SAN signal, as illustrated in FIG. 6A, and another single-line control signal may be used to drive local section drivers to generate more than one SAP signal, as illustrated in FIG. 6B. The single-line control signal may propagate to the local section drivers for the SAN signal and the SAP signal through sections near the control block 132 to sections far from the control block 132 within the memory bank 102. Accordingly, the timing variations between the SAN signals and the SAP signals may be reduced across the sections within the memory bank, which improves the sense margin and also improves the system performance. In some embodiments, timing control technology and circuits may be used to control the timing between the SAN signal and the SAP signal.

FIGS. 4A and 4B illustrate an embodiment of control circuitry using a single-line control signal (e.g., the RSAP signal) to drive local section drivers for generating both the SAN signal (e.g., the SAN signal 304) and the SAP signal (e.g., the SAP signal 310). FIG. 4A may include a first circuitry portion of the control circuitry, and FIG. 4B may include a second circuitry portion of the control circuitry. Although the RSAP signals are used to drive local section drivers for generating both the SAN signal and the SAP signal in the embodiment illustrated in FIGS. 4A and 4B, in other embodiments, the RSAN signals may be used to drive local section drivers for generating both the SAN signal and the SAP signal. In addition, although three SAN signals and three SAP signals are illustrated in FIGS. 4A and 4B, respectively, in other embodiment, other numbers (e.g., 1, 2, 4….) of SAN signals or SAP signals may be used.

FIG. 4A is a circuit diagram of control circuitry 400 implementing the RSAP signal rather than the RSAN signal to drive local section drivers for the SAN signal. In FIG. 4A, an RSAP signal 402 (e.g., the RSAP1 signal) from the control block 132 is used rather than an RSAN signal (e.g., the RSAN1 signal) from the control block 132 to drive local section drivers to generate a SAN signal 430 (e.g., the SAN1 signal). The RSAP signal 402 may be transmitted to a NAND gate 404 in a local section of the memory bank 102, and an enable signal (e.g., EN) may be used to enable the NAND gate 404. For example, only when EN has a value of “1”, the output of the NAND gate 404 is related to the signal 402; when EN has a value of “0”, the output of the AND gate 404 is “1” regardless of the value of the signal 402. An output 406 of the NAND gate 404 may be transmitted to a local VSAN level shifter 408. The VSAN level shifter 408 may be used to convert the logic levels of the output 406 (e.g., V_{PERI} ) to the logic levels of the SAN signal 430 (e.g., VSAN). The output 410 of the VSAN level sifter 408 may be the inversion of the output 406 with the converted logic levels. The output 410 of the VSAN level shifter 408 may be transmitted to an inverter 412 (e.g., a complementary metal–oxide–semiconductor (CMOS) inverter), which may include a PMOS transistor 412-p coupled to a tunable voltage source having a value of VSAN and an NMOS transistor 412-n coupled to a voltage source VSS (e.g., ground). The output 414 of the inverter 412 may be coupled to an inverter 416 (e.g., a CMOS inverter), which may include a PMOS transistor 416-p coupled to a tunable voltage source having a value of VSAN and an NMOS transistor 416-n. The output 414 of the inverter 412 may also be coupled to an optional inverter 420 (e.g., a CMOS inverter), which may include a PMOS transistor 420-p coupled to a tunable voltage source having a value of VSAN and an NMOS transistor 420-n coupled to the NMOS transistor 416-n. The output 418 of the inverter 416 and the output 422 of the inverter 420 may be combined to generate the SAN signal 430.

In FIG. 4A, an RSAP signal 432 (e.g., the RSAP2 signal) from the control block 132 is used rather than an RSAN signal (e.g., the RSAN2 signal) from the control block 132 to drive local section drivers to generate a SAN signal 460 (e.g., the SAN2 signal). The RSAP signal 432 may be transmitted to a NAND gate 434 in the local section of the memory bank 102, and an enable signal (e.g., EN) may be used to enable the NAND gate 434. An output 436 of the NAND gate 434 may be transmitted to a local VSAN level shifter 438. The VSAN level shifter 438 may be used to convert the logic levels of the output 436 (e.g., V_{PERI} ) to the logic levels of the SAN signal 460 (e.g., VSAN). 440 of the VSAN level sifter 438 may be the inversion of the output 436 with the converted logic levels. The output 440 of the VSAN level shifter 438 may be transmitted to an inverter 442 (e.g., a CMOS inverter), which may include a PMOS transistor 442-p coupled to a tunable voltage source having a value of VSAN and an NMOS transistor 442-n coupled to a voltage source VSS (e.g., ground). The output 444 of the inverter 442 may be coupled to an inverter 446 (e.g., a CMOS inverter), which may include a PMOS transistor 446-p coupled to a tunable voltage source having a value of VSAN and an NMOS transistor 446-n. The output 444 of the inverter 442 may also be coupled to an optional inverter 450 (e.g., a CMOS inverter), which may include a PMOS transistor 450-p coupled to a tunable voltage source having a value of VSAN and an NMOS transistor 450-n coupled to the NMOS transistor 446-n. The output 448 of the inverter 446 and the output 452 of the inverter 450 may be combined to generate the SAN signal 460.

In FIG. 4A, an RSAP signal 462 (e.g., the RSAP3 signal) from the control block 132 is used rather than an RSAN signal (e.g., the RSAN3 signal) from the control block 132 to drive local section drivers to generate a SAN signal 490 (e.g., the SAN3 signal). The RSAP signal 462 may be transmitted to a NAND gate 464 in the local section of the memory bank 102, and an enable signal (e.g., EN) may be used to enable the NAND gate 464. An output 466 of the NAND gate 464 may be transmitted to a local VSAN level shifter 468. The VSAN level shifter 468 may be used to convert the logic levels of the output 466 (e.g., V_{PERI} ) to the logic levels of the SAN signal 490 (e.g., VSAN). The output 470 of the VSAN level sifter 468 may be the inversion of the output 466 with the converted logic levels. The output 470 of the VSAN level shifter 468 may be transmitted to an inverter 472 (e.g., a CMOS inverter), which may include a PMOS transistor 472-p coupled to a tunable voltage source having a value of VSAN and an NMOS transistor 472-n coupled to a voltage source VSS (e.g., ground). The output 474 of the inverter 472 may be coupled to an inverter 476 (e.g., a CMOS inverter), which may include a PMOS transistor 476-p coupled to a tunable voltage source having a value of VSAN and an NMOS transistor 476-n. The output 474 of the inverter 472 may also be coupled to an optional inverter 480 (e.g., a CMOS inverter), which may include a PMOS transistor 480-p coupled to a tunable voltage source having a value of VSAN and an NMOS transistor 480-n coupled to the NMOS transistor 476-n. The output 478 of the inverter 476 and the output 482 of the inverter 480 may be combined to generate the SAN signal 490.

FIG. 4B is a circuit diagram of control circuitry 500 implementing the same RSAP signals used in FIG. 4A to drive local section drivers for corresponding SAP signals. In FIG. 4B, the RSAP signal 402 (e.g., the RSAP1 signal) from the control block 132 is used to drive local section drivers to generate a SAP signal 530 (e.g., the SAP1 signal). The RSAP signal 402 may be transmitted to an AND gate 502 in the section of the memory bank 102, and an enable signal (e.g., EN) may be used to enable the AND gate 502. For example, only when EN has a value of “1”, the output of the AND gate 502 is related to the signal 402; when EN has a value of “0”, the output of the AND gate 502 is “0” regardless of the value of the signal 402. The output of the AND gate 502 and a reference voltage source Vr may be input into a NOR gate 504. The output 506 of the NOR gate 504 may be transmitted to a local VCOMP level shifter 508 in the section. The VCOMP level shifter 508 may be used to convert the logic levels of the output 506 (e.g., V_{PERI} ) to the logic levels of the SAP signal 530 (e.g., VCOMP). The output 510 of the VCOMP level shifter 508 may be transmitted to an inverter 512 (e.g., a CMOS inverter), which may include a PMOS transistor 512-p coupled to a tunable voltage source having a value of VCOMP and an NMOS transistor 512-n coupled to a voltage source VSS (e.g., ground). The output 514 of the inverter 512 may be coupled to an inverter 516 (e.g., a CMOS inverter), which may include a PMOS transistor 516-p coupled to a tunable voltage source having a value of VCOMP and an NMOS transistor 516-n coupled to a voltage source VSS (e.g., ground). The output 518 of the inverter 516 may be coupled to an inverter 520 (e.g., a CMOS inverter), which may include a PMOS transistor 520-p coupled to a tunable voltage source having a value of VCOMP and an NMOS transistor 520-n coupled to a voltage source VSS (e.g., ground). The output 518 may also be coupled to an inverter 524 (e.g., a CMOS inverter), which may include a PMOS transistor 524-p coupled to a tunable voltage source having a value of VCOMP and an NMOS transistor 524-n coupled to a voltage source VSS (e.g., ground). The output 522 of the inverter 520 and the output 526 of the inverter 524 may be combined to generate the SAP signal 530.

In FIG. 4B, the RSAP signal 432 (e.g., the RSAP2 signal) from the control block 132 is used to drive local section drivers to generate a SAP signal 560 (e.g., the SAP2 signal). The RSAP signal 432 may be transmitted to an AND gate 532 in the section of the memory bank 102, and an enable signal (e.g., EN) may be used to enable the AND gate 532. The output of the AND gate 532, together with a reference voltage source Vr, may be input into a NOR gate 534. The output 536 of the NOR gate 534 may be transmitted to a local VCOMP level shifter 538 in the section. The VCOMP level shifter 538 may be used to convert the logic levels of the output 536 (e.g., V_{PERI} ) to the logic levels of the SAP signal 560 (e.g., VCOMP). The output 540 of the VCOMP level shifter 538 may be transmitted to an inverter 542 (e.g., a CMOS inverter), which may include a PMOS transistor 542-p coupled to a tunable voltage source having a value of VCOMP and an NMOS transistor 542-n coupled to a voltage source VSS (e.g., ground). The output 544 of the inverter 542 may be coupled to an inverter 546 (e.g., a CMOS inverter), which may include a PMOS transistor 546-p coupled to a tunable voltage source having a value of VCOMP and an NMOS transistor 546-n coupled to a voltage source VSS (e.g., ground). The output 548 of the inverter 546 may be coupled to an inverter 550 (e.g., a CMOS inverter), which may include a PMOS transistor 550-p coupled to a tunable voltage source having a value of VCOMP and an NMOS transistor 550-n coupled to a voltage source VSS (e.g., ground). The output 548 may also be coupled to an inverter 554 (e.g., a CMOS inverter), which may include a PMOS transistor 554-p coupled to a tunable voltage source having a value of VCOMP and an NMOS transistor 554-n coupled to a voltage source VSS (e.g., ground). The output 552 of the inverter 550 and the output 556 of the inverter 554 may be combined to generate the SAP signal 560.

In FIG. 4B, the RSAP signal 462 (e.g., the RSAP3 signal) from the control block 132 is used to drive local section drivers to generate a SAP signal 590 (e.g., the SAP3 signal). The RSAP signal 462 may be transmitted to an AND gate 562 in the section of the memory bank 102, and an enable signal (e.g., EN) may be used to enable the AND gate 562. The output of the AND gate 562, together with a reference voltage source Vr, may be input into a NOR gate 564. The output 566 of the NOR gate 564 may be transmitted to a local VCOMP level shifter 568 in the section. The VCOMP level shifter 568 may be used to convert the logic levels of the output 566 (e.g., V_{PERI} ) to the logic levels of the SAP signal 560 (e.g., VCOMP). The output 570 of the VCOMP level shifter 568 may be transmitted to an inverter 572 (e.g., a CMOS inverter), which may include a PMOS transistor 572-p coupled to a tunable voltage source having a value of VCOMP and an NMOS transistor 572-n coupled to a voltage source VSS (e.g., ground). The output 574 of the inverter 572 may be coupled to an inverter 576 (e.g., a CMOS inverter), which may include a PMOS transistor 576-p coupled to a tunable voltage source having a value of VCOMP and an NMOS transistor 576-n coupled to a voltage source VSS (e.g., ground). The output 578 of the inverter 576 may be coupled to an inverter 580 (e.g., a CMOS inverter), which may include a PMOS transistor 580-p coupled to a tunable voltage source having a value of VCOMP and an NMOS transistor 580-n coupled to a voltage source VSS (e.g., ground). The output 578 may also be coupled to an inverter 584 (e.g., a CMOS inverter), which may include a PMOS transistor 584-p coupled to a tunable voltage source having a value of VCOMP and an NMOS transistor 584-n coupled to a voltage source VSS (e.g., ground). The output 582 of the inverter 580 and the output 586 of the inverter 584 may be combined to generate the SAP signal 590.

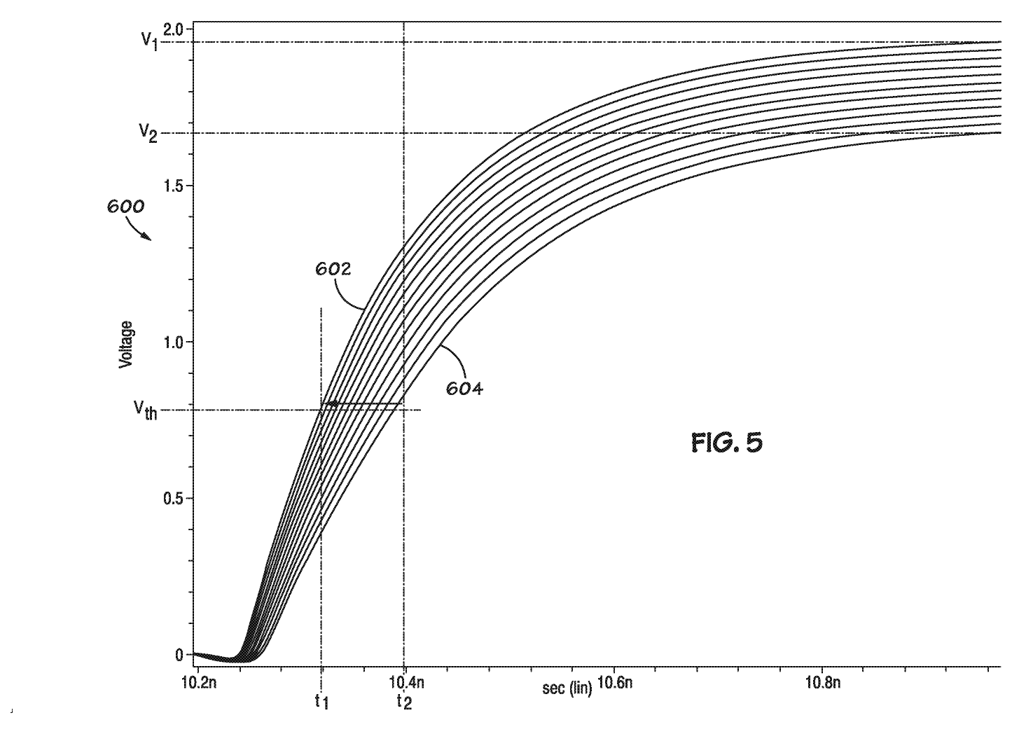

As illustrated in FIGS. 4A and 4B, the SAN signal and the SAP signal may be generated using a single-line control signal, which may reduce or eliminate the timing variations between the SAN signal and the SAP signal across the sections within the memory bank 102. The timing between the RNL signal (e.g., the RNL signal 280), which is turned on by the SAN signal (e.g., the SAN signal 304), and the ACT signal (e.g., the ACT signal 252), which is turned by the SAP signal (e.g., the SAP signal 310), may be controlled through voltage-level changes (e.g., VSACN, VCOMP) in the local section drivers. For instance, the VSAN level shifters (e.g., VSAN level shifter 408, 438, 468) may be used to convert the logic levels (e.g., VPERI) to the logic levels of the SAN signal (e.g., VSAN). The VCOMP level shifters (e.g., VCOMP level shifter 508, 538, 568) may be used to convert the logic levels (e.g., VPERI) to the logic levels of the SAP signal (e.g., VCOMP). Increasing or decreasing the values of VSAN or VCOMP may increase or decrease the voltage values of the SAN signal and the SAP signal. The voltage values of the SAN signal and the SAP signal may change the timing between the RNL signal (e.g., the RNL signal 280) and the ACT signal (e.g., the ACT signal 252) because the switch devices (e.g., the transistor 302, the transistor 308) for the ACT signal and the RNL signal may be turned on faster with larger magnitude of voltage difference between gate and source of the switch devices, as illustrated in FIG. 5. In addition, increasing or decreasing the values of VSAN or VCOMP at the corresponding level shifters and associated circuitry (e.g., inverters 412, 416, 420, 512, 516, 520, 524) may directly adjust the timing between the SAN signal and the SAP signal. Moreover, the level shifters may be adjusted to be controlled by either signal rising edge, which may provide fine tuning of timing control, or falling edge, which may provide coarse timing control. For example, the VSAN level shifters of FIG. 4A are controlled by signal rising edge, while the VCOMP level shifters of FIG. 4B are controlled by signal falling edge.

FIG. 5 is a timing diagram 600 illustrating a relationship of the maximum magnitude of the voltage difference between the gate and the source of a switch device (e.g., the transistor 302, the transistor 308) and the turn on time of the switch device. For example, a curve 602 shows the magnitude of the voltage difference, with the maximum value of V1, with respect to time during the turning on period. A curve 604 shows the magnitude of the voltage difference, with the maximum value of V2 (V2<V1), with respect to time during the turning on period. As illustrated in FIG. 5, the magnitude of the voltage difference may reach the threshold value Vth, which turns on the switch device, at time t1 for the curve 602 and at time t2 for the curve 604, with t2>t1.

FIGS. 6A and 6B illustrate a second embodiment of control circuitry using a single-line control signal (e.g., a SAN_ON signal) to drive local section drivers for generating more than one SAN signal and another single-line control signal (e.g., a SAP_ON signal) to drive local section drivers for generating more than one SAP signal. FIG. 6A may include a first circuitry portion of the control circuitry, and FIG. 6B may include a second circuitry portion of the control circuitry. Although three SAN signals and three SAP signals are illustrated in FIGS. 6A and 6B, respectively, in other embodiment, other numbers (e.g., 1, 2, 4….) of SAN signals or SAP signals may be used.

FIG. 6A is a circuit diagram of control circuitry 700 implementing a SAN_ON signal to drive local section drivers for generating more than one SAN signal to reduce the timing variations. In FIG. 6A, only one signal, a SAN_ON signal 702, is used to drive local section drivers to generate more than one SAN signal (e.g., SAN1, SAN2, and SAN3), and the RSAN signals (e.g., RSAN1, RSAN2, RSAN3) are used to enable corresponding SAN signals. In FIG. 6A, the SAN_ON signal 702 from the control block 132 is used to drive local section drivers to generate the SAN signal 430 (e.g., the SAN1 signal), the SAN signal 460 (e.g., the SAN2 signal), and the SAN signal 490 (e.g., the SAN3 signal).

The SAN_ON signal 702 may be transmitted to a NAND gate 704 in the local section of the memory bank 102, and an enable signal (e.g., EN) may be used to enable the NAND gate 704. In the embodiment illustrated in FIG. 6A, only one VSAN level shifter 708 may be used to generate the three SAN signals 430, 460, and 490 rather than using a respective VSAN level shifter (e.g., the VSAN level shifter 408, the VSAN level shifter 438, the VSAN level shifter 468) for each SAN signal, which improves area efficiency of the memory devices. The output 706 of the NAND gate 704 may be transmitted to the local VSAN level shifter 708 in the section. The VSAN level shifter 708 may be used to convert the logic levels of the output 706 (e.g., V_{PERI}) to the logic levels of the SAN signals (e.g., VSAN). The output 710 of the VSAN level sifter 708 may be the inversion of the output 706 with the converted logic levels.

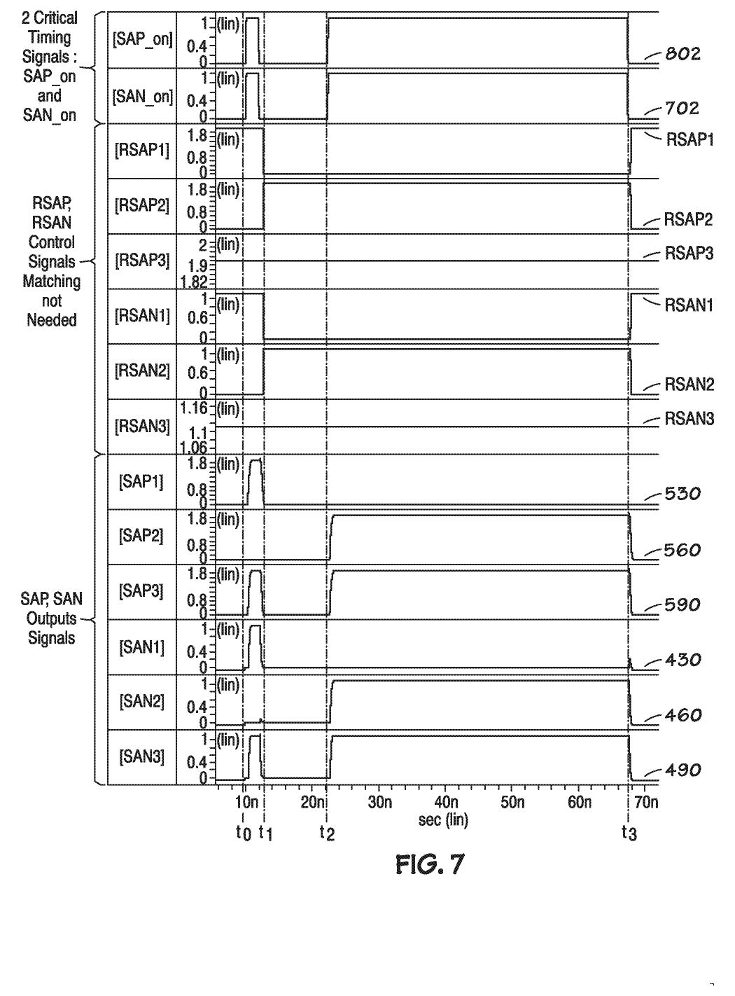

The output 710 of the VSAN level shifter 708 may be transmitted to the inverter 412, the inverter 432, and the inverter 472. An NMOS transistor 712 may be used to couple the NMOS transistor 412-n of the inverter 412 to the voltage source VSS (e.g., ground). The RSAN1 signal may be coupled to the gate of the NMOS transistor 712 to switch on/off the NMOS transistor 712. When the NMOS transistor 712 is turned on (e.g., when the RSAN1 signal has a logic high), the inverter 412 is connected to the voltage source VSS (e.g., ground) and thereby activated. A PMOS transistor 714 may be used to couple the output 414 of the inverter 412 to a voltage source VSAN. The RSAN1 signal may be coupled to the gate of the PMOS transistor 714 to switch on/off the PMOS transistor 714. When the PMOS transistor 714 is turned on (e.g., when the RSAN1 signal has a logic low), the output 414 is connected to the voltage source VSAN. Accordingly, the inverter 412 is controlled by the SAN_ON signal 702 and the RSAN1 signal, as illustrated in FIG. 7.

For example, when SAN_ON signal has a logic high, the output 710 has a logic high, and the NMOS transistor 412-n is turned on. However, if the RSAN1 signal has a logic low, the NMOS transistor 712 is not turned on and the NMOS transistor 412-n is not connected to the voltage source VSS (e.g., ground). In addition, when the RSAN1 signal has a logic low, the PMOS transistor 714 is turned on, and the output 414 is connected to the voltage source VSAN and has a logic high. On the other hand, when the SAN_ON signal 702 has a logic low, the output 710 has a logic low, and the NMOS transistor 412-n is not turned on, but the PMOS transistor 412-p is turned on and thereby connect the output 414 to the voltage source VSAN. Accordingly, the output 414 is connected to the voltage source VSAN and has a logic high. Therefore, when the SAN_ON signal 702 is on (e.g., has a logic high), the SAN signals (e.g., SAN1, SAN2, SAN3) may be on or off, which is determined by corresponding RSAN signals (e.g., RSAN1, RSAN2, RSAN3). When the SAN_ON signal 702 is off (e.g., has a logic low), all the SAN signals (e.g., SAN1, SAN2, SAN3) are turned off.

Similarly, an NMOS transistor 742 may be used to couple the NMOS transistor 442-n of the inverter 442 to the voltage source VSS (e.g., ground). The RSAN2 signal may be coupled to the gate of the NMOS transistor 742 to switch on/off the NMOS transistor 742. When the NMOS transistor 742 is turned on (e.g., when the RSAN2 signal has a logic high), the inverter 442 is connected to the voltage source VSS (e.g., ground) and thereby activated. A PMOS transistor 744 may be used to couple the output 444 of the inverter 442 to a voltage source VSAN. The RSAN2 signal may be coupled to the gate of the PMOS transistor 744 to switch on/off the PMOS transistor 744. When the PMOS transistor 744 is turned on (e.g., when the RSAN2 signal has a logic low), the output 444 is connected to the voltage source VSAN. Accordingly, the inverter 442 is controlled by the SAN_ON signal 702 and the RSAN2 signal, as illustrated in FIG. 7.

Similarly, an NMOS transistor 772 may be used to couple the NMOS transistor 472-n of the inverter 472 to the voltage source VSS (e.g., ground). The RSAN3 signal may be coupled to the gate of the NMOS transistor 772 to switch on/off the NMOS transistor 772. When the NMOS transistor 772 is turned on (e.g., when the RSAN3 signal has a logic high), the inverter 472 is connected to the voltage source VSS (e.g., ground) and thereby activated. A PMOS transistor 774 may be used to couple the output 474 of the inverter 472 to a voltage source VSAN. The RSAN3 signal may be coupled to the gate of the PMOS transistor 774 to switch on/off the PMOS transistor 774. When the PMOS transistor 774 is turned on (e.g., when the RSAN3 signal has a logic low), the output 474 is connected to the voltage source VSAN. Accordingly, the inverter 472 is controlled by the SAN_ON signal 702 and the RSAN3 signal, as illustrated in FIG. 7.

FIG. 6B is a circuit diagram of control circuitry 800 implementing a SAP_ON signal to drive local section drivers for generating more than one SAP signal to reduce the timing variations. In FIG. 6B, only one signal, a SAP_ON signal 802, is used to drive local section drivers to generate more than one SAP signal (e.g., SAP1, SAP2, and SAP3), and the RSAP signals (e.g., RSAP1, RSAP2, RSAP3) are used to enable corresponding SAP signals. In FIG. 6B, the SAP_ON signal 802 from the control block 132 is used to drive local section drivers to generate the SAP signal 530 (e.g., the SAP1 signal), the SAP signal 560 (e.g., the SAP2 signal), and the SAP signal 590 (e.g., the SAP3 signal).

The SAP_ON signal 802 may be transmitted to a NAND gate 804 in the local section of the memory bank 102, and an enable signal (e.g., EN) may be used to enable the NAND gate 804. In the embodiment illustrated in FIG. 6B, only one VCOMP level shifter 808 may be used to generate the three SAP signals 530, 560, and 590 rather than using a respective VCOMP level shifter (e.g., the VCOMP level shifter 508, the VCOMP level shifter 538, the VCOMP level shifter 568) for each SAP signal, which improves area efficiency of the memory devices. The output 806 of the NAND gate 804 may be transmitted to the local VCOMP level shifter 808 in the section. The VCOMP level shifter 808 may be used to convert the logic levels of the output 806 (e.g., V_{PERI}) to the logic levels of the SAP signals (e.g., VCOMP). The output 810 of the VCOMP level sifter 808 may have the converted logic levels. The output 810 of the VCOMP level shifter 808 may be transmitted to an inverter 812 (e.g., a CMOS inverter), which may include a PMOS transistor 812-p coupled to a voltage source having a value of VCOMP and an NMOS transistor 812-n coupled to a voltage source VSS (e.g., ground).

In the embodiment illustrated in FIG. 6B, the output 814 of the inverter 812 may be used to generate the three SAP signals 530, 560, and 590 rather than using a respective inverter (e.g., the inverter 512, the inverter 542, the inverter 572,) for each SAP signal. As illustrated in FIG. 6B, the output 814 may be coupled to three inverters, the inverter 516, the inverter 546, and the inverter 576. An NMOS transistor 816 may be used to couple the NMOS transistor 516-n of the inverter 516 to the voltage source VSS (e.g., ground). The RSAP1 signal may be coupled to the gate of the NMOS transistor 816 to switch on/off the NMOS transistor 816. When the NMOS transistor 816 is turned on (e.g., when the RSAP1 signal has a logic high), the inverter 516 is connected to the voltage source VSS (e.g., ground) and thereby activated. A PMOS transistor 818 may be used to couple the output 518 of the inverter 516 to a voltage source VCOMP. The RSAP1 signal may be coupled to the gate of the PMOS transistor 818 to switch on/off the PMOS transistor 818. When the PMOS transistor 818 is turned on (e.g., when the RSAP1 signal has a logic low), the output 518 is connected to the voltage source VCOMP. Accordingly, the inverter 516 is controlled by the SAP_ON signal 802 and the RSAP1 signal, as illustrated in FIG. 7.

For example, when the SAP_ON signal 802 has a logic high, the output 814 has a logic high, the NMOS transistor 516-n is turned on and the PMOS transistor 516-p is turned off. However, if the RSAP1 signal has a logic low, the NMOS transistor 816 is not turned on and the NMOS transistor 516-n is not connected to the voltage source VSS (e.g., ground). In addition, when the RSAP1 signal has a logic low, the PMOS transistor 818 is turned on and the output 518 is connected to the voltage source VCOMP, accordingly the output 518 has a logic high, which is not an inversion of the output 814. On the other hand, when the SAP_ON signal 802 has a logic low, the output 814 has a logic low, and the NMOS transistor 516-n is not turned on, but the PMOS transistor 516-p is turned on and thereby connect the output 518 to the voltage source VCOMP. Accordingly, the output 518 is connected to the voltage source VCOMP and has a logic high. Therefore, when the SAP_ON signal 802 is on (e.g., has a logic high), the SAP signals (e.g., SAP1, SAP2, SAP3) may be on or off, which is determined by corresponding RSAP signals (e.g., RSAP1, RSAP2, RSAP3). When the SAP_ON signal 802 is off (e.g., has a logic low), all the SAP signals (e.g., SAP1, SAP2, SAP3) are turned off.

Similarly, an NMOS transistor 846 may be used to couple the NMOS transistor 546-n of the inverter 546 to the voltage source VSS (e.g., ground). The RSAP2 signal may be coupled to the gate of the NMOS transistor 846 to switch on/off the NMOS transistor 846. When the NMOS transistor 846 is turned on (e.g., when the RSAP2 signal has a logic high), the inverter 546 is connected to the voltage source VSS (e.g., ground) and thereby activated. A PMOS transistor 848 may be used to couple the output 548 of the inverter 546 to a voltage source VCOMP. The RSAP2 signal may be coupled to the gate of the PMOS transistor 848 to switch on/off the PMOS transistor 848. When the PMOS transistor 848 is turned on (e.g., when the RSAP2 signal has a logic low), the output 548 is connected to the voltage source VCOMP. Accordingly, the inverter 546 is controlled by the SAP_ON signal 802 and the RSAP2 signal, as illustrated in FIG. 7.

Similarly, an NMOS transistor 876 may be used to couple the NMOS transistor 576-n of the inverter 576 to the voltage source VSS (e.g., ground). The RSPA3 signal may be coupled to the gate of the NMOS transistor 876 to switch on/off the NMOS transistor 876. When the NMOS transistor 876 is turned on (e.g., when the RSPA3 signal has a logic high), the inverter 576 is connected to the voltage source VSS (e.g., ground) and thereby activated. A PMOS transistor 878 may be used to couple the output 578 of the inverter 576 to a voltage source VCOMP. The RSPA3 signal may be coupled to the gate of the PMOS transistor 878 to switch on/off the PMOS transistor 878. When the PMOS transistor 878 is turned on (e.g., when the RSPA3 signal has a logic low), the output 578 is connected to the voltage source VCOMP. Accordingly, the inverter 576 is controlled by the SAP_ON signal 802 and the RSPA3 signal, as illustrated in FIG. 7.

FIG. 7 is a timing diagram illustrating relationships of the signals SAN_ON, SAP_ON, RSANs, RSAPs, SANs, and SAPs. As illustrated in FIG. 7, during time period t0 to t1, the SAN_ON signal 702 has a logic high. Since both the RSAN1 and RSAN3 signals have logic high during the time period t0 to t1, both the SAN1 430 and SAN3 490 signals have logic high during the time period t0 to t1. Since the RSAN2 signal has logic low during the time period t0 to t1, the SAN2 460 signal has logic low during the time period t0 to t1.

During time period t1 to t2, the SAN_ON signal 702 has a logic low, all SAN signals (e.g., SAN1 430, SAN2 460, SAN3 490) have logic low during the time period t1 to t2 regardless of the values of RSAN signals (e.g., even though both the RSAN2 and the RSAN3 signals have logic high during the time period t1 to t2).

During time period t2 to t3, the SAN_ON signal 702 has a logic high. Since both the RSAN2 and RSAN3 signals have logic high during the time period t2 to t3, both the SAN2 460 and SAN3 490 signals have logic high during the time period t2 to t3. Since the RSAN1 signal has logic low during the time period t2 to t3, the SAN2 430 signal has logic low during the time period t2 to t3.

As illustrated in FIG. 7, during time period t0 to t1, the SAP_ON signal 802 has a logic high. Since both the RSAP1 and RSAP3 signals have logic high during the time period t0 to t1, both the SAP1 530 and SAP3 590 signals have logic high during the time period t0 to t1. Since the RSAP2 signal has logic low during the time period t0 to t1, the SAP2 560 signal has logic low during the time period t0 to t1.

During time period t1 to t2, the SAP_ON signal 802 has a logic low, all SAP signals (e.g., SAP1 530, SAP2 560, SAP3 590) have logic low during the time period t1 to t2 regardless of the values of RSAP signals (e.g., even though both the RSAP2 and the RSAP3 signals have logic high during the time period t1 to t2).

During time period t2 to t3, the SAP_ON signal 802 has a logic high. Since both the RSAP2 and RSAP3 signals have logic high during the time period t2 to t3, both the SAP2 560 and SAP3 590 signals have logic high during the time period t2 to t3. Since the RSAP1 signal has logic low during the time period t2 to t3, the SAP2 530 signal has logic low during the time period t2 to t3.

FIG. 8 is a circuit diagram of control circuitry 900, which may be another embodiment for the second circuitry portion of the control circuitry (with FIG. 6A being the first circuitry portion of the control circuitry), using a single-line control signal (e.g., a SAN_ON signal 702) from the bank control block 132 to drive local section drivers for generating more than one SAN signals (e.g., SAN1, SAN2, SAN3 of FIG. 6A) and more than one SAP signals (e.g., SAP1, SAP2, SAP3 of FIG. 6B). In the embodiment illustrated in FIG. 8, only one signal, the SAN_ON signal 702, may propagate from the control block 132 to the section of the memory bank 102 and be used to drive local section drivers for generating more than one SAN signals (e.g., SAN1, SAN2, SAN3 of FIG. 6A) and more than one SAP signals (e.g., SAP1, SAP2, SAP3 of FIG. 6B). In other embodiments, the SAP_ON signal 802 may be used to drive local section drivers for generating more than one SAN signals (e.g., SAN1, SAN2, SAN3 of FIG. 6A) and more than one SAP signals (e.g., SAP1, SAP2, SAP3 of FIG. 6B).

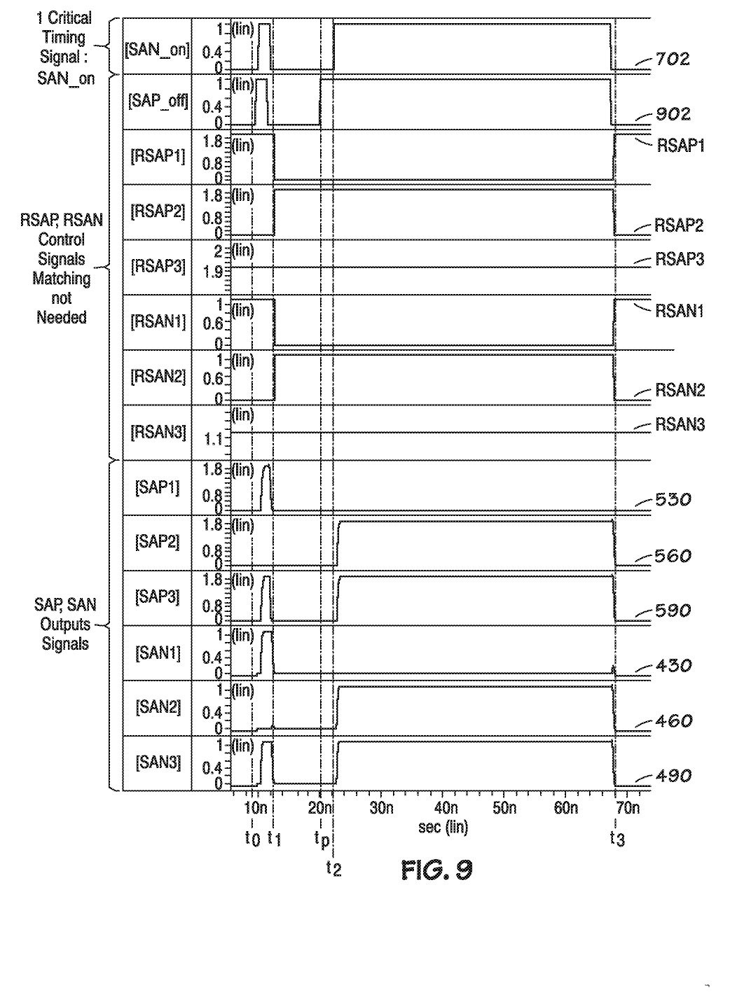

As previously illustrated in FIG. 6A, the SAN_ON signal 702 is coupled to a NAND gate 704. The output 706 of the NAND gate 704 may be transmitted to the local VSAN level shifter 708 in the section to generate more than one SAN signals (e.g., SAN1, SAN2, SAN3 of FIG. 6A). In addition, the output 706 of the NAND gate 704 may be coupled to the local VCOMP level shifter 808 in the section via a circuit 901 to generate more than one SAP signals (e.g., SAP1, SAP2, SAP3 of FIG. 6B). A SAP_OFF signal 902 may be used together with the SAN_ON signal 702 to generate the more than one SAP signals (e.g., SAP1, SAP2, SAP3 of FIG. 6B). For instance, the circuit 901 may include an inverter 904, and the output 706 may be coupled to the inverter 904. The output 906 of the inverter is an inversion of the output 706, accordingly, the output 906 has the same logic (e.g., logic high, logic low) as the SAN_ON signal. The circuit 901 may also include an AND gate 908, and the output 906 of the inverter 904 and the SAP_OFF signal 902 may be input into the AND gate 908. The output of the AND gate 908 and a voltage VSS may be input into a NOR gate 910, and an output 912 of the NOR gate 910 may be transmitted to the local VCOMP level shifter 808 in the section. Accordingly, the output 912 may be controlled by both the SAN_ON signal 702 and the SAP_OFF signal 902. The output 912 may be coupled to the VCOMP level shifter 808 in the section. The VCOMP level shifter 808 may be used to convert the logic levels of the output 912 (e.g., V_{PERI}) to the logic levels of the SAP signals (e.g., VCOMP). The output 810 of the VCOMP level sifter 808 may have the converted logic levels (e.g., VCOMP). Since the output 912 is controlled by both the SAN_ON signal 702 and the SAP_OFF signal 902 (e.g., via the AND gate 908), the generated SAP signals (e.g., the SAP signal 530, the SAP signal 560, the SAP signal 590) may be controlled by both the SAN_ON signal 702 and the SAP_OFF signal 902, as illustrated in FIG. 9.

FIG. 9 is a timing diagram illustrating relationships of SAN_ON, SAP_OFF, RSAN, RSAP, SAN, and SAP. As illustrated in FIG. 9, during time period t0 to t1, the SAN_ON signal 702 has a logic high. Since both the RSAN1 and RSAN3 signals have logic high during the time period t0 to t1, both the SAN1 430 and SAN3 490 signals have logic high during the time period t0 to t1. Since the RSAN2 signal has logic low during the time period t0 to t1, the SAN2 460 signal has logic low during the time period t0 to t1. During time period t1 to t2, the SAN_ON signal 702 has a logic low, all SAN signals (e.g., SAN1 430, SAN2 460, SAN3 490) have logic low during the time period t1 to t2 regardless of the values of RSAN signals (e.g., even though both the RSAN2 and the RSAN3 signals have logic high during the time period t1 to t2). During time period t2 to t3, the SAN_ON signal 702 has a logic high. Since both the RSAN2 and RSAN3 signals have logic high during the time period t2 to t3, both the SAN2 460 and SAN3 490 signals have logic high during the time period t2 to t3. Since the RSAN1 signal has logic low during the time period t 2to t3, the SAN2 430 signal has logic low during the time period t2 to t3.

As illustrated in FIG. 9, during time period t0 to t1, both the SAN_ON signal 702 and the SAP_OFF signal 902 have a logic high. Since both the RSAP1 and RSAP3 signals have logic high during the time period t0 to t1, both the SAP1 530 and SAP3 590 signals have logic high during the time period t0 to t1. Since the RSAP2 signal has logic low during the time period t0 to t1, the SAP2 560 signal has logic low during the time period t0 to t1.

During time period t1 to tp, both the SAP_OFF signal 902 and the SAN_ON signal 702 have a logic low, all SAP signals (e.g., SAP1 530, SAP2 560, SAP3 590) have logic low during the time period t1 to t2 regardless of the values of RSAP signals (e.g., even though both the RSAP2 and the RSAP3 signals have logic high during the time period t1 to tp).

During time period tp to t2, the SAP_OFF signal 902 has a logic high, however, since SAN_ON 702 has a logic low, all SAP signals (e.g., SAP1 530, SAP2 560, SAP3 590) have logic low during the time period t1 to tp regardless of the values of RSAP signals (e.g., even though both the RSAP2 and the RSAP3 signals have logic high during the time period tp to t2).

During time period t2 to t3, both the SAN_ON signal 702 and the SAP_OFF signal 902 have a logic high. Since both the RSAP2 and RSAP3 signals have logic high during the time period t2 to t3, both the SAP2 560 and SAP3 590 signals have logic high during the time period t2 to t3. Since the RSAP1 signal has logic low during the time period t2 to t3, the SAP2 530 signal has logic low during the time period t2 to t3.

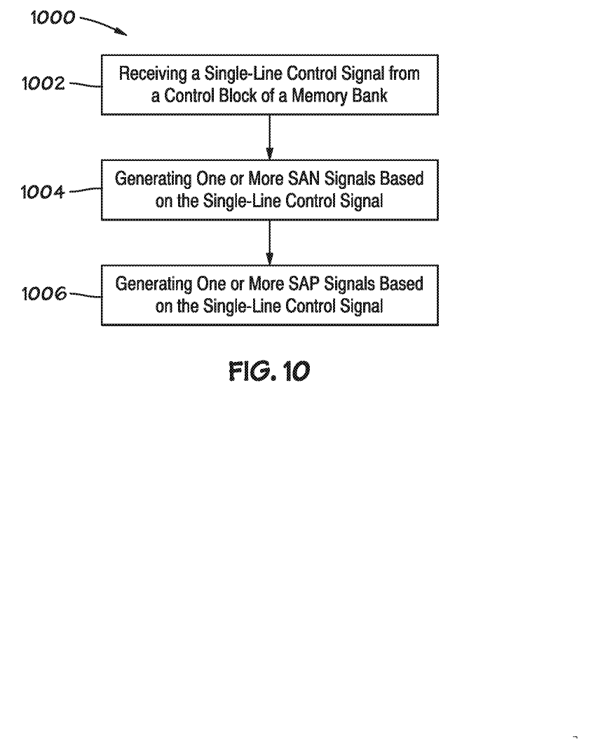

FIG. 10 is a flowchart illustrating an embodiment of a method 1000 for implementing a single-line control signal propagating from a control block of a memory bank to a section of the memory bank to generate both the SAN signal and the SAP signal. At block 1002, a single-line control signal (e.g., the signals 402, 432, 462, 702) propagating from the control block of the memory bank to the sections of the memory bank may be received by circuitry of a section of the memory bank. At block 1004, the single-line control signal may be used to drive local section drivers to generate one or more SAN signals, as illustrated in FIGS. 4A and 6A. At block 1006, the single-line control signal may be used to drive local section drivers to generate one or more SAP signals, as illustrated in FIGS. 4B and 8. In some embodiments, two single-line control signals (e.g., the SAN_ON signal 702 and the SAP_ON signal 802) propagating from the control block of the memory bank to the section of the memory bank may be used to drive local section drivers to generate the SAN signals and the SAP signals, respectively, as illustrated in FIGS. 6A and 6B. Although the embodiment illustrated in FIG. 10 is described in a particular order, it should be noted that the method 1000 may be performed in any suitable order and is not limited to the order presented herein.

Accordingly, the technical effects of the present disclosure include techniques for mitigating (e.g., reducing or eliminating) timing variations of control signals (e.g., SAN signals, SAP signals) for the sense amplifier of a memory device. A single-line control signal from a control block of a memory bank of the memory device may be used to drive local section drivers to generate both the SAN signal(s) and the SAP signal(s) for the sense amplifier. In some embodiments, a single-line control signal from the control block of the memory bank may be used to generate a SAN signal and a SAP signal. In some embodiments, a single-line control signal from the control block of the memory bank may be used to generate more than one SAN signal, and another single-line control signal from the control block of the memory bank may be used to generate more than one SAP signal. In some embodiments, a single-line control signal from the control block of the memory bank may be used to generate more than one SAN signal and more than one SAP signal. The single-line control signal may propagate to the local section drivers for generating the SAN signal and the SAP signal through sections near the control block to sections far from the control block within the memory bank. Timing control technology and circuitry may be used to control the timing among the SAN signals and the SAP signals. Accordingly, the timing variations among the SAN signals and the SAP signals may be reduced across the sections within the memory bank, which improves the sense margin of the SAs and also improves the system performance. In addition, the current technology and methods improve area efficiency in the memory devices since less components may be used to generate the SAN signals and the SAP signals.

In the illustrated embodiments above, the memory devices and systems are primarily described in the context of devices incorporating DRAM storage media. Memory devices configured in accordance with other embodiments of the present technology, however, may include other types of memory devices and systems incorporating other types of storage media, including PCM, SRAM, FRAM, RRAM, MRAM, read only memory (ROM), erasable programmable ROM (EPROM), electrically erasable programmable ROM (EEROM), ferroelectric, magnetoresistive, and other storage media, including non-volatile, flash (e.g., NAND and/or NOR) storage media.

It should be understood that logically-equivalent circuitry may be used to implement the systems and methods described above. For example, a logical XOR gate may be replaced via a logically-equivalent combination of NOT gates, AND gates, Inverse NOT gates, OR gates, NAND gates, NOR gates, or the like.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. An apparatus, comprising:
a memory bank comprising one or more sense amplifiers enabled based on one or more SAN signals and one or more SAP signals; and
control circuitry configured to:
receive a control signal from a control block of the memory bank;
generate the one or more SAN signals based on the control signal; and
generate the one or more SAP signals based on the control signal.

2. The apparatus of claim 1, wherein the control circuitry comprises a level shifter configured to generate more than one SAN signal.

3. The apparatus of claim 1, wherein the control circuitry comprises a level shifter configured to generate more than one SAP signal.

4. The apparatus of claim 1, wherein the control circuitry comprises a first level shifter for generating a SAN signal of the one or more SAN signals and a second level shifter for generating a SAP signal of the one or more SAP signals, and wherein a timing between the SAN signal and the SAP signal is adjusted based on a first voltage of the first level shifter and a second voltage of the second level shifter.

5. The apparatus of claim 4, wherein the timing between the SAN signal and the SAP signal is adjusted based on a first control method of the first level shifter and a second control method of the second level shifter.

6. The apparatus of claim 5, wherein the first control method comprises a rising edge control or a falling edge control.

7. The apparatus of claim 1, wherein the control circuitry comprises a first switch device and a second switch device to enable generating a first SAN signal of the one or more SAN signals, wherein the first switch device and the second switch device are enabled based on a first control signal.

8. The apparatus of claim 7, wherein the first switch device comprises an NMOS transistor and the second switch device comprises a PMOS transistor.

9. The apparatus of claim 8, wherein the control circuitry comprises a third switch device and a fourth switch device to enable generating a second SAN signal of the one or more SAN signals, wherein the third switch device and the fourth switch device are enabled based on a second signal.

10. The apparatus of claim 1, wherein the control circuitry is configured to generate the one or more SAP signals based on another control signal.

11. Control circuitry of a memory device, comprising:
a first circuitry portion configured to generate one or more SAN signals for a memory bank based on a control signal from a control block of the memory bank; and
a second circuitry portion configured to generate one or more SAP signals for the memory bank based on the control signal.

12. The control circuitry of claim 11, wherein the first circuitry portion comprises a level shifter configured to generate more than one SAN signal.

13. The control circuitry of claim 11, wherein the second circuitry portion comprises a level shifter configured to generate more than one SAP signal.

14. The control circuitry of claim 11, wherein the first circuitry portion comprises a first level shifter and the second circuitry portion comprises a second level shifter, and wherein a timing between a SAN signal of the one or more SAN signals and a SAP signal of the one or more SAP signals is adjusted based on a first voltage of the first level shifter and a second voltage of the second level shifter.

15. The control circuitry of claim 11, wherein the first circuitry portion comprises a first switch device and a second switch device to enable generating of a first SAN signal of the one or more SAN signals, wherein the first switch device and the second switch device are enabled based on a first control signal.

16. The control circuitry of claim 15, wherein the first switch device comprises an NMOS transistor and the second switch device comprises a PMOS transistor.

17. A method, comprising:
receiving a single-line control signal from a control block of a memory bank;
generating one or more SAN signals for the memory bank based on the single-line control signal; and
generating one or more SAP signals for the memory bank based on the single-line control signal.

18. The method of claim 17, comprising:
enabling a respective generation of each of the one or more SAN signals based on a respective control signal.

19. The method of claim 17, comprising:
enabling a respective generation of each of the one or more SAP signals based on a respective control signal.

20. The method of claim 17, comprising:
generating the one or more SAP signals based on another control signal.
